(19) United States
(12) Patent Application Publication
(10) Pub. No.: US 2026/0209029 A1
(43) Pub. Date: Jul. 23, 2026

(54) REDUCTION OF NON-LINEAR MOTION OF MEMS MASSES

(71) Applicant: InvenSense, Inc., San Jose, CA (US)

(72) Inventors: Mohammad H. Asadian Ardakani, San Jose, CA (US); Daryosh Vatanparvar, Fremont, CA (US); Lorenzo Bertini, Cascina (IT); Robert Hennessy, San Jose, CA (US)

(21) Appl. No.: 19/035,614

(22) Filed: Jan. 23, 2025

(51) Int. Cl. B81B 3/00

(52) U.S. Cl. CPC B81B 3/0051; B81B 2201/0235; B81B 2201/0242; B81B 2203/0163; B81B 2203/0307; B81B 2203/056

(57) ABSTRACT

A MEMS inertial sensor includes a levered component within the MEMS layer of the sensor that transfers motion to one or more movable masses. The levered component moves in a rotational motion about a pivot point and is connected to one of the masses by a flexible coupling. The flexible coupling includes multiple spring elements that are connected and configured to transfer only a linear motion in one direction to the connected mass while eliminating a transfer of the rotational motion to the connected mass.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

MEMS inertial sensor are designed as a suspended spring-mass system within a MEMS layer of the inertial sensor, with springs and masses designed and configured to facilitate movements in particular directions in response to particular forces. In many MEMS inertial sensor designs, multiple springs and masses interact in a manner in which some levered components rotate about a pivot point, for example, to transfer movements between multiple components or axes. These rotational movements, when propagated to masses within the system such as drive or proof masses, may impart rotational forces on those masses at the frequency of the rotational movement and at harmonics of that frequency. Existing methods to suppress these rotational movements on these masses such as imparting electrostatic forces or using symmetric guided mass systems add significant complexity while requiring additional power consumption and occupying additional space within the MEMS layer.

### SUMMARY

In an embodiment of the present disclosure a MEMS sensor comprises a movable mass within a MEMS layer of the MEMS sensor and a levered component within the MEMS layer that rotates within a horizontal plane of the MEMS layer about a point of rotation such that the levered component moves in both a first direction in the horizontal plane and a second direction in the horizontal plane during the rotation, wherein the first direction and the second direction are perpendicular. The MEMS sensor can further comprise a flexible coupling that connects to the movable mass and to the levered component, wherein the flexible coupling transfers movement from the levered component to the movable mass in the first direction, and is compliant in the second direction such that the rotation of the levered component does not cause movement of the movable mass in the second direction.

In an embodiment of the present disclosure a MEMS sensor comprises a first movable mass within a MEMS layer of the MEMS sensor and a second movable mass within the MEMS layer and coupled to the first movable mass via one or more springs. The MEMS sensor can further comprise a levered component within the MEMS layer that rotates within a horizontal plane of the MEMS layer about a point of rotation. The MEMS sensor can further comprise a flexible coupling that connects to the first movable mass and to the levered component, wherein the flexible coupling transfers movement from the levered component to the movable mass such that the first movable mass moves only in a first direction, and wherein the one or more springs transfer the movement in the first direction to the second movable mass without imparting a rotation on the second movable mass.

In an embodiment of the present disclosure a MEMS sensor comprises a first movable mass within a MEMS layer of the MEMS sensor and a second movable mass within the MEMS layer and coupled to the first movable mass via one or more springs. The MEMS sensor can further comprise a levered component within the MEMS layer that rotates within a horizontal plane of the MEMS layer about a point of rotation at a first frequency. The MEMS sensor can further comprise a flexible coupling that connects to the first movable mass and to the levered component, wherein the flexible coupling transfers movement from the levered component to the movable mass and the one or more springs transfer movement from the first movable mass to the second movable mass such that the second movable mass does not have any rotational movement at a harmonic of the first frequency.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 depicts an exemplary MEMS system in accordance with an embodiment of the present disclosure;

FIG. 2A depicts a first example configuration of a spring-mass system propagating rotational movement to movable masses;

FIG. 2B depicts a second example configuration of a spring-mass system propagating rotational movement to movable masses;

FIGS. 3A-3B depict modification of the first example configuration of the spring-mass system of FIG. 2A to remove the propagation of rotational motion to movable masses in accordance with an embodiment of the present disclosure;

FIG. 4 depicts a first example spring-mass system configuration of FIG. 3B to remove the propagation of rotational motion to movable masses in accordance with an embodiment of the present disclosure;

FIG. 5 depicts a second example spring-mass system configuration of FIG. 3B to remove the propagation of rotational motion to movable masses in accordance with an embodiment of the present disclosure;

FIGS. 6A-6B depict modification of the second example configuration of the spring-mass system of FIG. 2A to remove the propagation of rotational motion to movable masses in accordance with an embodiment of the present disclosure;

FIG. 7 depicts an example spring-mass system configuration of FIG. 6B to remove the propagation of rotational motion to movable masses in accordance with an embodiment of the present disclosure;

FIG. 8 depicts an exemplary schematic of a spring-mass system including a multi-spring flexible coupling, in accordance with an embodiment of the present disclosure;

FIG. 9 depicts an exemplary schematic of a spring-mass system including a flexible coupling with multiple springs and a shuttle mass, in accordance with an embodiment of the present disclosure;

FIG. 10 depicts an exemplary schematic of a spring-mass system including a multi-spring flexible coupling, in accordance with an embodiment of the present disclosure;

FIG. 11 depicts an exemplary schematic of a spring-mass system including a multi-spring flexible coupling, in accordance with an embodiment of the present disclosure;

FIG. 12 depicts an exemplary schematic of a spring-mass system including a multi-spring flexible coupling, in accordance with an embodiment of the present disclosure;

FIG. 13 depicts an exemplary schematic of a spring-mass system including a multi-spring flexible coupling, in accordance with an embodiment of the present disclosure; and

FIG. 14 depicts example steps of removing the propagation of rotational motion to movable masses in accordance with an embodiment of the present disclosure.

### DETAILED DESCRIPTION

In MEMS inertial sensors, the intended displacement of sensing elements such as proof masses along a sense direction is used for the detection or measurement of a physical phenomenon (e.g., seismic motion, rotation, acceleration, etc.). Any unwanted or unintended mechanical motion can distort the signal (e.g., a capacitive signal based on the position of the proof mass relative to a fixed sense electrode) detected by the sense electronics. For example, when a linear mass-spring system that is driven in a specific direction is mechanically coupled to a lever system (e.g., in a MEMS gyroscope), an unwanted rotational (e.g., angular) motion is induced on the linear mass orthogonal to the driven motion, which in certain implementations may occur twice the drive frequency (e.g., the second harmonic of the drive frequency).

A flexible mechanical coupling element can be introduced between the linear spring-mass elements and the lever system to decouple angular motion of the levered components from the linear motion of the driven spring-mass system. The decoupling of the rotational and linear motion is performed in a manner such that forces are still transferred between rotational and linear components (e.g., allowing a drive and/or sense force to be transferred between these components), but without imparting undesired motions such as rotational/angular motions onto the linear spring-mass components. As a result, the linear spring-mass component coupled to the levered component via the flexible coupling moves only in the desired linear pattern, and only linear motions are further propagated to other spring-mass components. In this manner, the entire linear drive and sense system of the linear-spring components is limited to intended linear movements, avoiding undesired rotational motion of these components such as at harmonics (e.g., a second harmonic) of the frequency of the rotational motion.

The flexible coupling provides this decoupling without the need for additional electrostatic forces to suppress rotation and without the need for paired or symmetric spring-mass systems to physically limit rotational motion that is propagated to linear spring-mass components. Rotational motion within the linear spring-mass components is eliminated, including the second harmonic rotational motion. With the flexible coupling, a smaller footprint of the MEMS structure is possible while having increased accuracy, improved sensitivity, and lower noise within the sense path and circuitry (e.g., enabling increased capacitance-to-voltage (“C2V”) conversion gain.

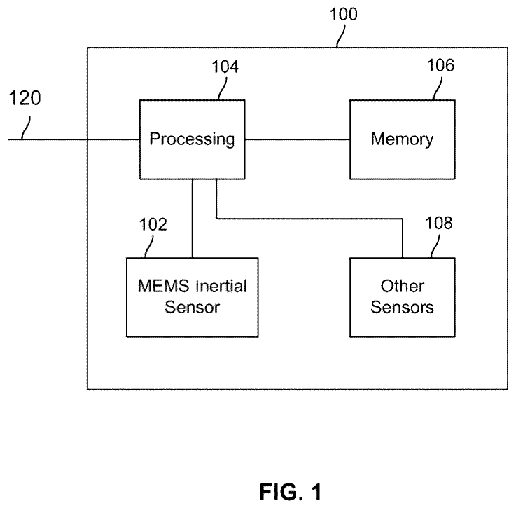

FIG. 1 shows an illustrative MEMS system 100 in accordance with an embodiment of the present disclosure. Although particular components are depicted in FIG. 1, it will be understood that other suitable combinations of the MEMS, processing components, memory, and other circuitry may be utilized as necessary for different applications and systems. In accordance with the present disclosure, the MEMS system may include a MEMS inertial sensor 102 as well as additional sensors 108. Although the present disclosure will be described in the context of signals received from MEMS inertial sensors, it will be understood that the flexible decoupling system and components of the present disclosure may be utilized with other MEMS sensor or devices in which there are movable MEMS components that respectively include both rotational and linear movements and are coupled within the MEMS layer of the sensor.

Processing circuitry 104 may include one or more components providing processing based on the requirements of the MEMS system 100. In some embodiments, processing circuitry 104 may include hardware control logic that may be integrated within a chip of a sensor (e.g., on a base substrate of a MEMS inertial sensor 102 or other sensors 108, or on an adjacent portion of a chip to the MEMS inertial sensor 102 or other sensors 108) to control the operation of the MEMS inertial sensor 102 or other sensors 108 and perform aspects of processing for the MEMS inertial sensor 102 or the other sensors 108. In some embodiments, the MEMS inertial sensor 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the MEMS inertial sensor 102 by interacting with the hardware control logic and processing signals received from MEMS inertial sensor 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the MEMS inertial sensor 102 or other sensors 108 may communicate directly with external circuitry (e.g., via a serial bus or direct connection to sensor outputs and control inputs), in an embodiment the processing circuitry 104 may process data received from the MEMS inertial sensor 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the MEMS inertial sensor 102 and other sensors 108 into appropriate measurement units (e.g., based on settings provided by other computing units communicating over the communication interface 110) and perform more complex processing to determine measurements such as orientation or Euler angles, and in some embodiments, to determine from sensor data whether a particular activity (e.g., walking, running, braking, skidding, rolling, etc.) is taking place. In some embodiments, some or all of the conversions or calculations may take place on the hardware control logic or other on-chip processing of the MEMS inertial sensor 102 or other sensors 108.

In some embodiments, certain types of information may be determined based on data from multiple MEMS gyroscopes 102 and other sensors 108 in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimenstional cameras, industrial automation, and numerous other applications.

A suspended spring mass system defining the movable components of the MEMS inertial sensor 102 may include multiple movable components, with some of the components (e.g., masses, lever arms, etc.) being levered components that are “hinged” such that they rotate about a pivot point and other components being linear spring-mass components suspended with an intention to move only linearly. For example, MEMS gyroscopes such as multi-axis MEMS gyroscopes may have levered components that facilitate transfer of drive forces into multiple directions along different drive axes. However, the levered components may also transfer or limit motion of the linear spring-mass components in a manner such that they also move in a rotational manner. In some instances, these rotational movements as they are propagated to other components within the linear spring-mass system (e.g., between drive or driven masses to proof masses) are experienced as a second harmonic of the frequency of the underlying rotational motion, resulting in significant undesired forces.

In some embodiments, designs of flexible couplings are implemented with combinations of beam and/or spring elements to connected within a hinged asymmetric mass-spring components. The flexible coupling is connected between hinged components and the linear spring-mass components. The flexible coupling provides rotational compliance between the levered component and the linear spring-mass components such that the rotation of levered components (e.g., lever arm) is not transmitted to the linear spring-mass components (e.g., a drive or driven mass, and via the drive or driven mass, to one or more proof masses). The flexible coupling facilitates the desired movement in the first direction but reduces stiffness in a second orthogonal direction that is due to the rotation.

In an example with multiple masses, the flexible coupling connects between a levered component (e.g., a lever arm) and a primary mass (e.g., a drive or driven mass), which in turn is coupled to a secondary mass (e.g., a proof mass or Coriolis mass) via spring elements. The lever is coupled to a shuttle mass of the flexible coupling has a swing motion that includes translation in a first direction, a second direction, and a rotation orthogonal to the first and second directions. The shuttle mass moves in the first direction, the second direction, and rotation orthogonal to the first and second directions, while spring elements of the flexible coupling couple the shuttle mass to the primary mass and transfer only the translation in the first direction to the primary mass in the first direction.

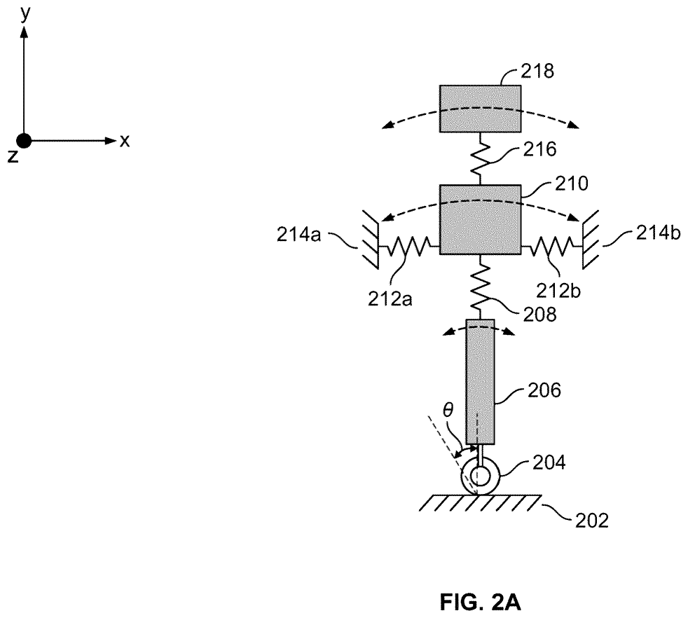

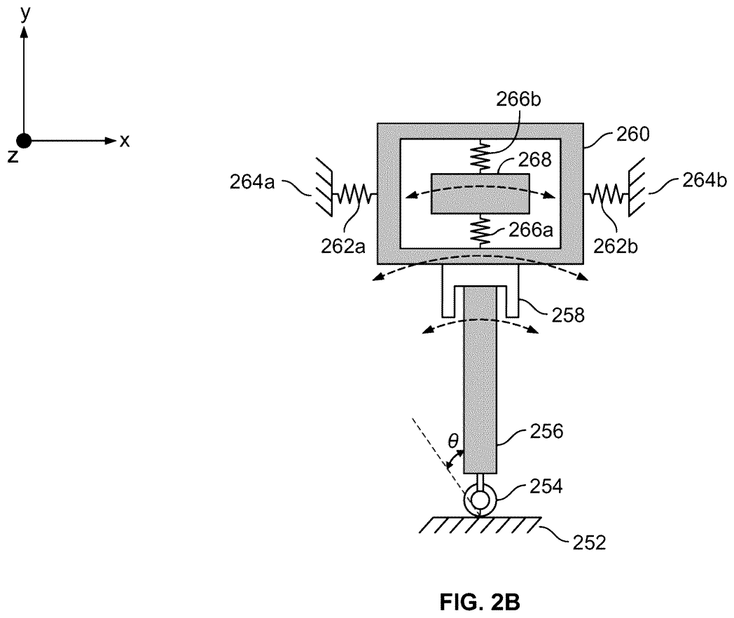

FIG. 2A depicts a first example configuration of a spring-mass system propagating rotational movement to movable masses. It will be understood that the exemplary spring mass system depicted in the schematic view of FIG. 2A, as well as the other spring-mass systems depicted herein, as depicted in a simplified schematic form that may represent a variety of sensor types (e.g., MEMS inertial sensors such as MEMS accelerometers or MEMS gyroscopes) and portions of those sensors (e.g., drive systems, sense systems, combinations, etc.). For example, the masses depicted in any of the figures herein may be any of drive masses, driven masses, lever arms, sense or proof masses, Coriolis masses, shuttle masses, or other similar components that are capable of movement within a MEMS sensor.

In the embodiment of FIG. 2A, a levered component 206 is attached to a hinge 204 that is affixed to an anchoring point 202. The levered component 206 has an angle θ of rotation about the hinge 204. A spring element 208 connects the levered component 206 to a movable mass 210. The levered component 206 is capable of rotational movement within the MEMS plane (e.g., within the x-y plane). The movable mass 210 connects to two spring elements 212, that are each affixed to their respective anchoring points 214. Another movable mass 218 is attached to movable mass 210 by means of a spring element 216.

Forces such as drive forces or external forces being sensed by the MEMS system (sense forces) cause movement of the interconnected components of FIG. 2A. For example, force applied to lever component 206 and/or movable mass 210 may cause the levered component 206 to rotate an angle of θ about the hinge. As this is a rotational movement, non-linear forces will be exerted along the x and y axes across the spring element 208, which restrict the movement of the movable mass 210 based on the same x-direction and y-direction components of the rotational movement as the lever arm. This rotational force is further may be applied to movable mass 218 via the spring element 216. In many embodiments, where the rotational movement is periodic (e.g., corresponds to a drive motion), the rotational movement of the levered component 206 and the movable mass 210 is at a frequency while the movement of the movable mass 218 is at a second harmonic of the frequency. This second harmonic movement of the movable mass 218 may be particularly difficult to filter, remove, or compensate for, resulting in degradation of sensor performance such as by reduced sensitivity and increased noise (e.g., at a movable mass 218 that functions as a proof mass).

Anchoring points (e.g., 202, 214) are generally present within spring-mass systems to suspend the movable components within the system. They serve to attach components to the base substrate (not shown) or handle (not shown) within a MEMS device and to constrain the range of motion of the movable components. Additionally, the anchoring points confer rigidity and structural stability to the entire MEMS device. They may be fabricated from a number of materials that are compatible with the MEMS fabrication process, including but not limited to silicon, polysilicon, metals (e.g., aluminum, platinum), polymers, composites, silicon nitride, or any combination thereof. There may be primary anchoring points 202, secondary anchoring points 214, tertiary anchoring points, or any number of anchoring points positioned at any location throughout a MEMS device. Anchoring points may attach to any component within a MEMS device. For example, a hinge 204 or a spring element 212 may be affixed to an anchoring point to limit their rotational freedom or provide a stable reference surface, respectively. Additionally, multiple components may attach to a singular anchoring point.

Hinges 204 are pivot points within spring-mass systems that enable the rotational movement of a component (e.g., levered component 206) around a specific axis. The rotational freedom permitted by the hinge 204 confer controllability of the angular displacement of components, which may ultimately impact the functionality of the MEMS device. The exact amount of rotational freedom of the hinge 204 may be controlled by fine-tuning its configuration (e.g., shape, material) during the fabrication process of the MEMS device. Hinges 204 are generally made from the same materials as the other components within the MEMS device, but may also contain dopants (e.g., metal alloys) for added flexibility or strength. The design of the hinge 204 may be that of thin beams, flexures, or any other configuration that allows for rotational movement. Any component within a MEMS device may attach to a hinge 204. For example, levered components 206 may be attached to hinges 204 to allow for controlled rotational movement about a particular axis. Generally, hinges 204 are also affixed to an anchoring point 202 to limit the degree of rotational freedom of the hinge 204. Multiple components may be attached to a singular hinge 204.

A levered component 206 within the spring-mass system is capable of rotating about a particular axis with an θ angle of rotation via attachment to a pivot point such as hinge 204 in FIG. 2A. The levered component 206 allows for the amplification and/or distribution of forces within a MEMS device. Additionally, it is able to redirect a particular force along another axis (e.g., transform a force that is purely along the x-axis into a force that is also along the y-axis), thus providing for translation of drive forces initially imparted along a first axis to also be translated to a perpendicular axis. One or multiple components may be attached to a single levered component 206. The location, material composition, electrical and physical properties, shape, dimensions (e.g., length), configuration, sensitivity, and degree of θ angle of rotation of the levered component 206 may vary across MEMS sensors and be controlled during the MEMS fabrication process. Any type of component may be attached to the levered component 206. In this embodiment, the levered component 206 is attached to a hinge 204 that confers a rotational axis to the component, as well as a spring element 208 that can redirect external forces along particular axes further throughout the MEMS device. In the event that an external force is applied to the MEMS device, the force may cause an θ angle of rotation of the levered component 206 about the hinge 204 that may in turn induce an applied force along another axis on the spring element 208. Due to its rotational freedom, every force that is applied to the levered component 206 may produce forces along multiple axes (e.g., x-axis and y-axis). Further, the generated movements within the MEMS device may be combinatorial such that both a linear direction of travel and a rotation occur simultaneously for a single component or for multiple components.

Energy may be stored and released within various spring elements (e.g., 208, 212, 216) throughout the system. When external forces are applied, spring elements compress and/or stretch, which allow them to store the kinetic energy as potential energy. This stored energy may be released elsewhere within the MEMS device due to the specific configuration of the system. The spring elements may be able use their potential energy to control the movement of other components (e.g., movable masses) and thus tune the functionality and output of the MEMS device. The geometry, number, material composition, thickness, and general configuration of the spring elements may vary across MEMS devices depending on a multitude of considerations. The precise design and configuration of the spring elements will have a direct impact on their rigidity and compliance, and the specific directions/axes of that rigidity and compliance. Each spring element (e.g., 208, 212, 216) has a respective spring constant that determines not only its natural frequency of oscillation and energy storing potential, but also the sensitivity and operational range of the element within the MEMS device. Any component (e.g., movable mass, anchoring point) may be connected to a spring element, and multiple types of components may be attached to a single spring element. For example, attaching a levered component 206 to one end of a spring element 208, while attaching a movable mass 210 to the other end of the spring element 208 may generate a system such that the rotational movement of the levered component 206 may transfer a force (e.g., non-linear) through the spring element 208 to the movable mass 210. Spring elements 216 may also connect multiple movable masses (e.g., 210, 218) together in order to transfer directional forces between multiple components.

Spring-mass systems contain movable masses (e.g., 210, 218) that are capable of moving or oscillating in response to forces such as drive forces and external forces. Movable masses are fabricated within the MEMS layer of the MEMS device. The location, number, shape, dimensions, mass, and configuration of the movable masses may vary across MEMS devices or within a single spring-mass system. Movable masses may be connected to any component within a MEMS device, but generally are connected to one or multiple spring elements. For example, the movable mass 210 is attached to four different spring elements (e.g., 208, 212a, 212b, 216). Constraining movement of the movable mass to a single axis or plane may be desirable for some MEMS devices. In some embodiments, a movable mass 210 may be connected to another movable mass 218, for example, in drive (or driven) mass and proof mass configurations. Each movable mass within a spring-mass system has a natural frequency where resonance occurs. As shown in FIG. 2, based on the configuration of the springs and connection to levered component 206, the movable masses (e.g., 210, 218) oscillate in a rotational manner similar to the levered components 206, such that the movements have components along both the x-axis and y-axis simultaneously.

FIG. 2B depicts a second example configuration of a spring-mass system propagating rotational movement to movable masses. This spring-mass system is similar to and functions in a similar manner as that of the spring-mass system in FIG. 2A. However, the spring element 258 that connects the levered component 256 to the movable mass 260 is of a different design, which allows for compliance of the spring element 258 in the x-direction, but not the y-direction. Thus, forces along the y-axis will be readily transferred through the spring element 258 while the mass 260 will be “dragged” along in the x-direction. Additionally, the shape of the movable mass 260 that is attached to spring element 258 was altered to take on a frame-shaped design. Such a design allows for the other movable mass 268 to be located within the perimeter of movable mass 260 and to be attached to the interior walls of the movable mass 260 via two spring elements (e.g., 266a, 266b).

The numbered elements of FIG. 2B are similar to and function in a similar manner as the components of FIG. 2A, such that the rotational movement of the levered component 256 is directly transferred to the movable mass 260 via spring element 258, and from movable mass 258 to movable mass 268 via springs 266a and 266b. Accordingly, based on the configuration of the springs and masses of FIG. 2B, the movable masses 260 and 268 oscillate in a rotational manner similar to the levered components 206, such that the movements have components along both the x-axis and y-axis simultaneously, based on the frequency of the oscillation of levered component 256. Based on the configuration of FIG. 2B, movable mass 268 may have its rotation at a second harmonic of this frequency.

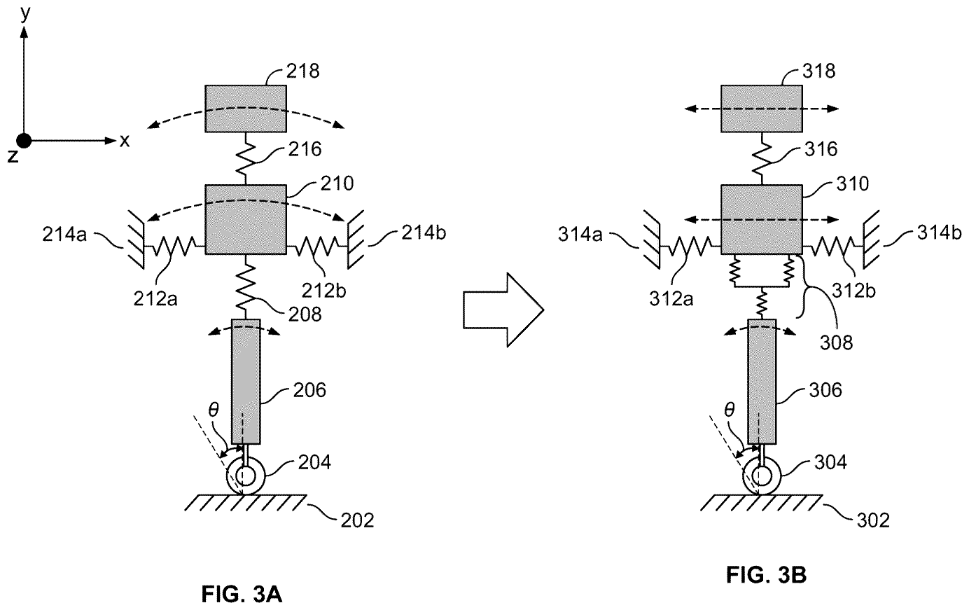

FIGS. 3A-3B depict modification of the first example configuration of the spring-mass system of FIG. 2A (depicted as 3A) to remove the propagation of rotational motion to movable masses in accordance with an embodiment of the present disclosure. FIG. 3A at the left retains the same components and numbering as FIG. 2A, and functions as previously described. FIG. 3B depicts identical components depicted and numbered similarly (with “3” replacing “2” in the first reference numeral) with spring element 208 replaced by multi-component flexible coupling 308. The underlying components (three springs) of the flexible coupling 308 are configured such that the y-direction component rotation of the levered component 306 is not transferred to either of the movable masses 310 or 318.

As is depicted by FIG. 3B, the springs of flexible coupling 308 are each configured for compliance in the y-direction but include a rigid coupling that translates motion in the x-direction (e.g., between the spring elements connected to movable mass 310, and bisected by the spring coupled to levered component 306). When the levered component rotates at an angle (e.g., to either side of a y-axis centered on the levered component 306), the y-direction component of the rotation is absorbed by the y-direction extension of the compliant spring elements of flexible coupling 306. The x-direction movement is translated to the movable mass 310 via the rigid x-direction portion of the flexible coupling. Because movable mass 310 only oscillates along a linear x-axis, movable mass 316 similarly has a linear x-axis oscillation.

This embodiment reduces noise and improves sensitivity for MEMS devices that require sensing linear movements of one or more of the movable masses 310/318 along a linear axis. Note that the systems and methods described herein are used to alter the movement of one or multiple movable masses along the y-axis, but similar methods may be used to restrict movement along other axes.

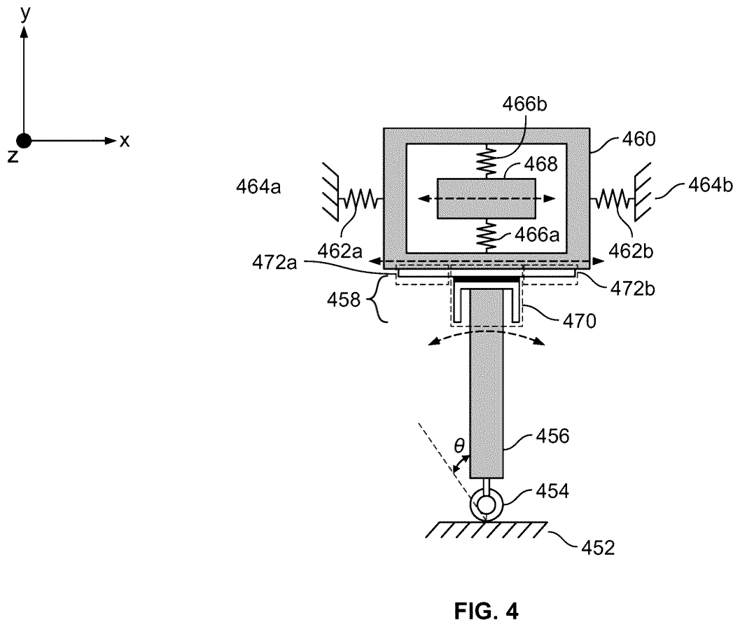

FIG. 4 depicts a first example spring-mass system configuration of FIG. 3B to remove the propagation of rotational motion to movable masses in accordance with an embodiment of the present disclosure. This spring-mass system is similar to and functions in a similar manner as that of the spring-mass system in FIG. 2B. However, a flexible coupling 458 is used to transfer forces between the levered component 456 and the movable mass 460. The levered component 456 is restricted to a rotational motion via hinge 454, which is anchored at anchor 452. Forces are transferred between levered component 456 and movable mass 460 via flexible coupling 458, which in turn includes a first spring element 470 and second spring elements 472 and 472b. Movable mass 460 in turn is coupled to transfer motion to nested movable mass 468 via springs 466a and 466b.

The numbered elements of FIG. 4 are similar to and function in a similar manner as the components of FIG. 2B. However, a flexible coupling 458 is used to transfer forces between the levered component 456 and the movable mass 460 in a manner such that the rotational motion of levered component 456 does not drive or restrict the movable mass in y-axis direction. The precise design and configuration of the flexible coupling 458 will have a direct impact on its compliance, and the specific direction/axis of that compliance (e.g., compliant along the x-axis). In this embodiment, a first spring element 470 is attached to the levered component 456, extends adjacent to levered component 456 in the y-axis direction in a manner (e.g., with bends) that provide partial compliance in the y-axis direction, and has a thicker rigid portion located between the levered component 456 and the movable mass 460 and extending in the x-axis direction to provide rigidity in the that x-axis direction. Second spring elements 472a and 472b are attached on respective sides to first spring element 470, extending along the length of movable mass 460 in a manner and with a thickness that allows the second spring elements 472a and 472b to be flexible along the y-direction when the levered component rotates with a y-axis movement component.

In this manner, when the levered component 456 rotates (e.g., at a frequency), the x-axis component of that movement is transferred between the levered component 456 and the movable mass 460 based on the rigid spring components of first spring element 470 and second spring elements 472a and 472b, while the y-axis component of the levered component 456 movement is not transferred to movable mass 460 based on the y-axis compliance of first spring element 470 and second spring elements 472a and 472b of flexible coupling 458. Because movable mass 460 only moves along the x-axis, the motion of movable mass 468 is similarly restricted to an x-axis oscillation.

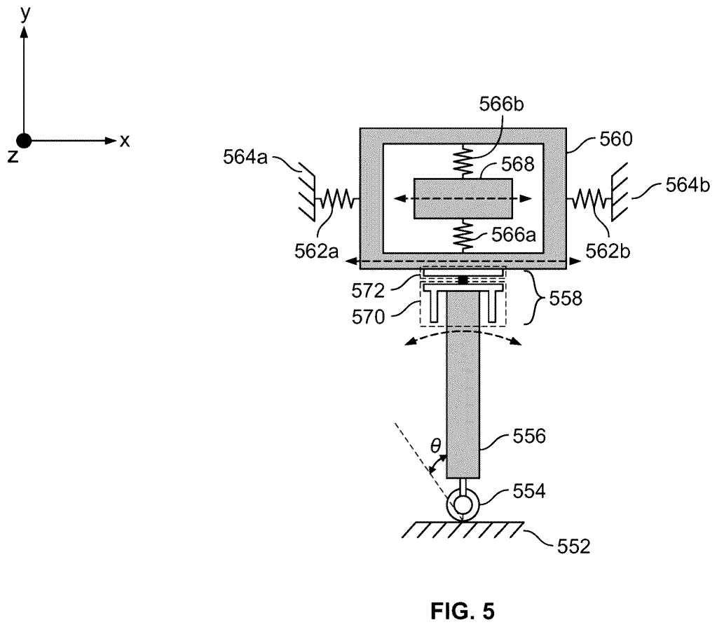

FIG. 5 depicts a second example spring-mass system configuration of FIG. 3B to remove the propagation of rotational motion to movable masses in accordance with an embodiment of the present disclosure. This spring-mass system is similar to and functions in a similar manner as that of the spring-mass system in FIG. 4. The levered component 556 is restricted to a rotational motion via hinge 554, which is anchored at anchor 552. Forces are transferred between levered component 556 and movable mass 560 via flexible coupling 558, which in turn includes a first spring element 570 and second spring element 572. Movable mass 560 in turn is coupled to transfer motion to nested movable mass 568 via springs 566a and 566b. However, the design of the first portion of the flexible coupling 570 and the second spring element 572 have been modified.

The numbered elements of FIG. 5 are similar to and function in a similar manner as the components of FIG. 4. In this embodiment, first spring element 570 is attached to the levered component 556, extends adjacent to levered component 556 in the y-axis direction in a manner (e.g., with bends) that provide partial compliance in the y-axis direction, and extends along the x-axis direction in a manner that is relatively rigid in the x-axis direction and provides compliance to movement along the y-axis direction. A thicker spring element portion connects between first spring element 570 and second spring element 572, with the second spring element 572 extending along the length of movable mass 560 in a manner and with a thickness that allows the second spring elements 572a to be flexible along the y-direction when the levered component 566 rotates with a y-axis movement component.

In this manner, when the levered component 556 rotates (e.g., at a frequency), the x-axis component of that movement is transferred between the levered component 556 and the movable mass 560 based on the rigid spring components of first spring element 570 and second spring element 572, while the y-axis component of the levered component 556 movement is not transferred to movable mass 560 based on the y-axis compliance of first spring element 570 and second spring elements 572 of flexible coupling 558. Because movable mass 560 only moves along the x-axis, the motion of movable mass 568 is similarly restricted to an x-axis oscillation.

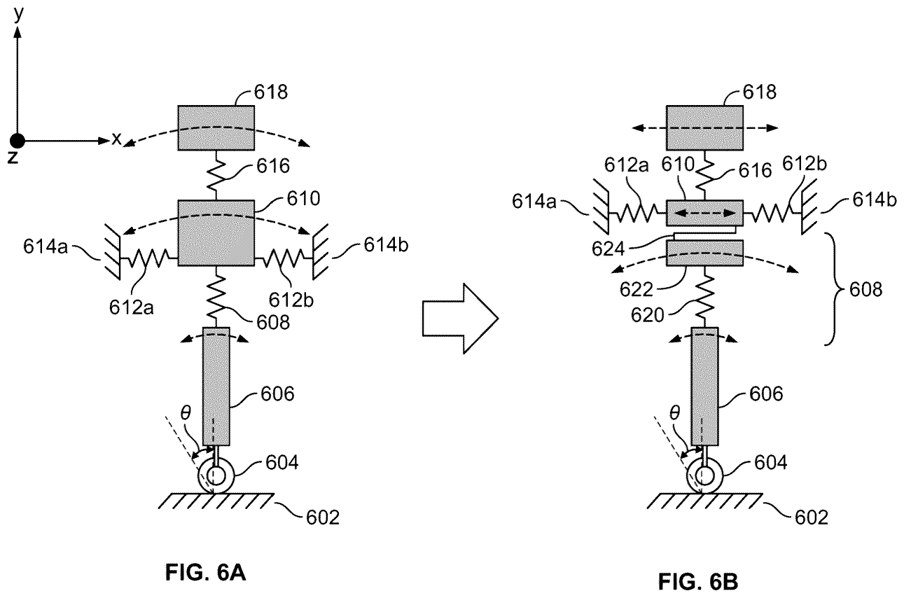

FIGS. 6A-6B depict modification of the example configuration of the spring-mass system of FIG. 2A to remove the propagation of rotational motion to movable masses in accordance with an embodiment of the present disclosure. Components of FIG. 2A function in the same manner as similarly numbered components of FIG. 2A. FIG. 6B depicts another example flexible coupling 608 including an intermediary (e.g., secondary) movable mass 622 connected to movable mass 610 via second spring element 624 and to the levered component 606 via first spring element 620.

As is depicted by FIG. 6B, the springs 620 and 624 of flexible coupling 608 are each configured for compliance in the y-direction, while the intermediary (e.g., secondary) movable mass 622 and second spring 624 are rigidly coupled along the x-direction. When the levered component 606 rotates at an angle (e.g., to either side of a y-axis centered on the levered component 606), the y-direction component of the rotation is absorbed by the y-direction extension of the compliant spring elements 620 and 624 of flexible coupling 606. The x-direction movement is translated to the movable mass 610 via the rigid x-direction portion of the intermediary (e.g., secondary) movable mass 622 and second spring element 624. Because movable mass 610 only oscillates along a linear x-axis, movable mass 616 similarly has a linear x-axis oscillation.

This embodiment reduces noise and improves sensitivity for MEMS devices that require sensing linear movements of one or more of the movable masses 610/618 along a linear axis. Further, removing unwanted oscillations of movable masses increases the amount of usable energy within the spring-mass system that may be used for other purposes (e.g., to generate a Coriolis motion in response to an angular velocity perpendicular to a drive motion). Note that the systems and methods described herein are used to alter the movement of one or multiple movable masses along the y-axis, but similar methods may be used to restrict movement along other axes.

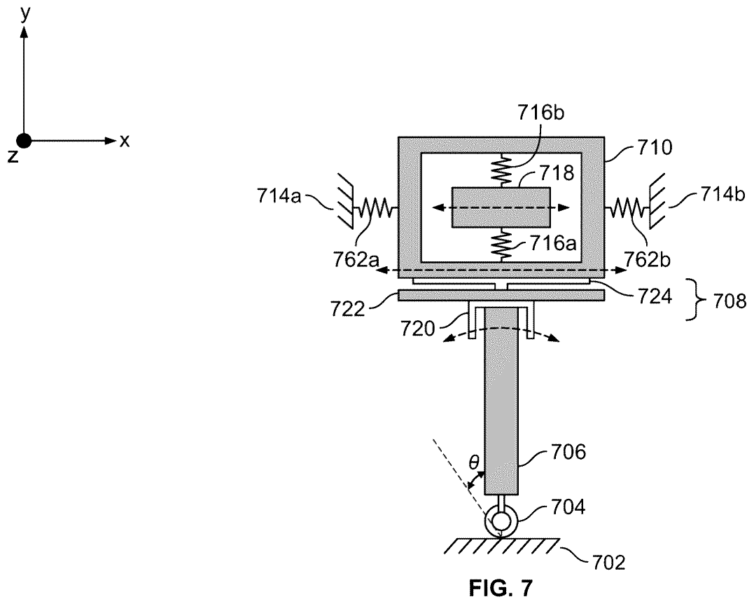

FIG. 7 depicts an example spring-mass system configuration of FIG. 6B to remove the propagation of rotational motion to movable masses in accordance with an embodiment of the present disclosure. This spring-mass system is similar to and functions in a similar manner as that of the spring-mass system in FIG. 6B, with like-numbered elements corresponding to similar components. In the embodiment of FIG. 7, movable mass 718 is nested inside of movable mass 710 and attached to interior surfaces of movable mass 710 via spring elements 716a and 716b. Flexible coupling element 708 connects between movable mass 710 and levered component 706, and includes a first spring element 720 connected to levered component 706, a second spring element 724 connected to movable mass 710, and an intermediary (e.g., secondary) movable mass 722 connected between first spring element 720 and second spring element 724. The first spring element 720 extends alongside and adjacent to levered component 706 and is capable of translating both x-direction and y-direction movement between levered component 706 and intermediary (e.g., secondary) movable mass 722 when levered component 706 rotates. In general, the illustrated example spring 720 may have flexibility in both x-direction and y-direction, with the spring 720 being less flexible in the y-direction than in the x-direction. The intermediary (e.g., secondary) movable mass 722 translates x-axis motion and y-axis motion to the second spring element 724, which is compliant in the y-direction and rigid in the x-direction, resulting in only x-axis movement being transferred between intermediary (e.g., secondary) movable mass 722 and movable mass 710. Because movable mass 710 oscillates only in the x-direction, movable mass 718 similarly moves only in the x-direction.

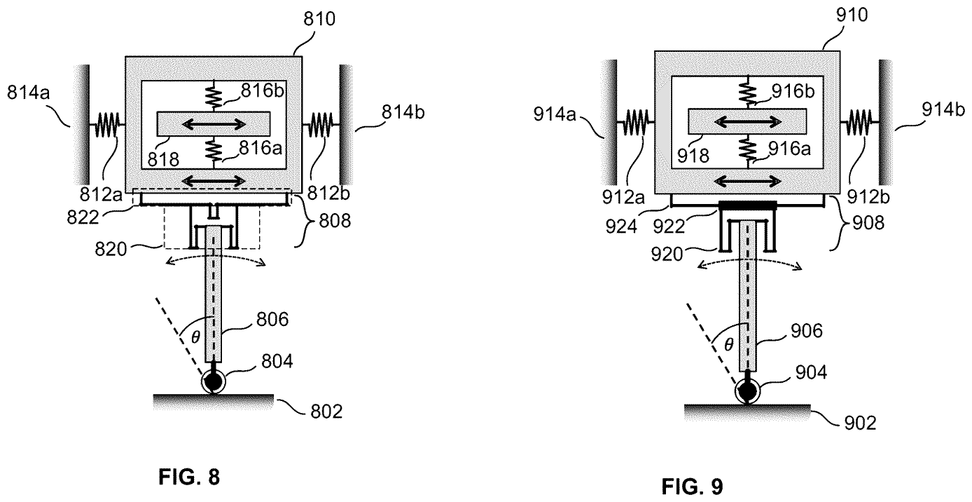

FIG. 8 depicts an exemplary schematic of a spring-mass system including a multi-spring flexible coupling, in accordance with an embodiment of the present disclosure. This spring-mass system is similar to and functions in a similar manner as that of the spring-mass system in FIGS. 3B, 4 and 5, with like-numbered elements corresponding to similar components. In the embodiment of FIG. 8, movable mass 818 is nested inside of movable mass 810 and attached to interior surfaces of movable mass 810 via spring elements 816a and 816b. Flexible coupling 808 connects between movable mass 810 and levered component 806, and includes a first spring element 820 connected to levered component 806 and second spring element 822, which in turn connects to movable mass 810. The first spring element 820 extends alongside and adjacent to levered component 806 and from levered component to connect to second spring element 822, is capable of translating both x-direction and y-direction movement between levered component 806 and second spring element 822 when levered component 806 rotates. The spring 820 may have flexibility in both x-direction and y-direction, with the spring 820 being less flexible in the y-direction than in the x-direction. The second spring element 822, which is compliant in the y-direction and rigid in the x-direction, resulting in only x-axis movement being transferred between levered component 806 and movable mass 810. The second spring 822 may have a notch, which may add rotational compliance. Because movable mass 810 oscillates only in the x-direction, movable mass 818 similarly moves only in the x-direction.

FIG. 9 depicts an exemplary schematic of a spring-mass system including a flexible coupling with multiple springs and a shuttle mass, in accordance with an embodiment of the present disclosure. This spring-mass system is similar to and functions in a similar manner as that of the spring-mass system in FIGS. 6A, 6B, and 7, with like-numbered elements corresponding to similar components. In the embodiment of FIG. 9, movable mass 918 is nested inside of movable mass 910 and attached to interior surfaces of movable mass 910 via spring elements 916a and 916b. Flexible coupling 908 connects between movable mass 910 and levered component 906, and includes a first spring element 920 connected to levered component 906, an intermediary (e.g., secondary) movable mass 922 connected between first spring element 920 and second spring element 924, and second spring element 924 connected between intermediary (e.g., secondary) movable mass 922 and movable mass 910. The first spring element 920 extends alongside and adjacent to levered component 906 and connects to intermediary (e.g., secondary) movable mass 922, and is capable of translating both x-direction and y-direction movement between levered component 906 and intermediary (e.g., secondary) movable mass 922 when levered component 906 rotates. The spring 920 may have flexibility in both x-direction and y-direction, with the spring 920 being less flexible in the y-direction than in the x-direction. The intermediary (e.g., secondary) movable mass 922 translates x-axis motion and y-axis motion to the second spring element 924, which is compliant in the y-direction and rigid in the x-direction, resulting in only x-axis movement being transferred between intermediary (e.g., secondary) movable mass 922 and movable mass 910. Because movable mass 910 oscillates only in the x-direction, movable mass 918 similarly moves only in the x-direction.

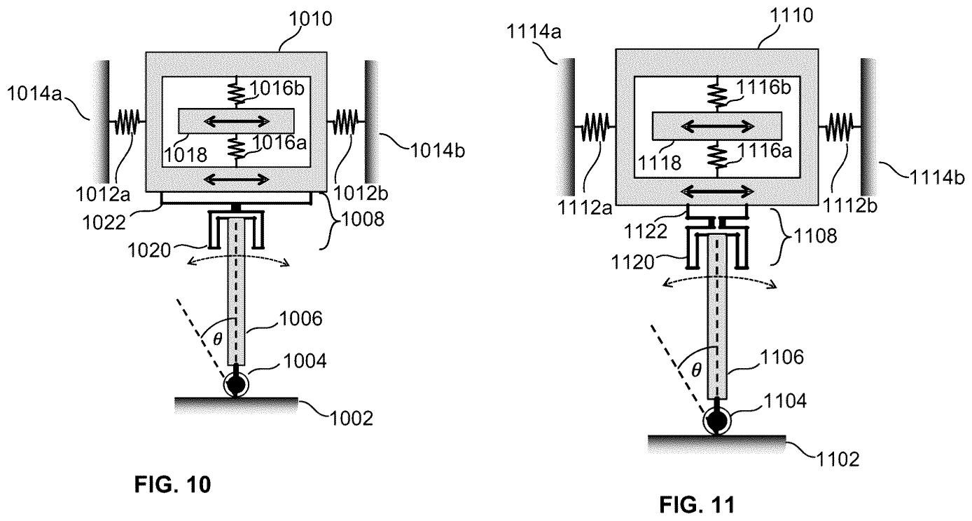

FIG. 10 depicts an exemplary schematic of a spring-mass system including a multi-spring flexible coupling, in accordance with an embodiment of the present disclosure. This spring-mass system is similar to and functions in a similar manner as that of the spring-mass system in FIGS. 3B, 4 and 5, with like-numbered elements corresponding to similar components. In the embodiment of FIG. 10, movable mass 1018 is nested inside of movable mass 1010 and attached to interior surfaces of movable mass 1010 via spring elements 1016a and 1016b. Flexible coupling 1008 connects between movable mass 1010 and levered component 1006, and includes a first spring element 1020 connected to levered component 1006 and second spring element 1022, which in turn connects to movable mass 1010. The first spring element 1020 extends alongside and adjacent to levered component 1006 and from levered component to a relatively thick terminating point that connects to second spring element 1022, and is capable of translating both x-direction and y-direction movement between levered component 1006 and second spring element 1022 when levered component 1006 rotates. The spring 1020 may have flexibility in both x-direction and y-direction, with the spring 1020 being less flexible in the y-direction than in the x-direction. The second spring element 1022, which is compliant in the y-direction and rigid in the x-direction, extends adjacent to the bottom surface of movable mass 1010, resulting in only x-axis movement being transferred between levered component 1006 and movable mass 1010. Because movable mass 1010 oscillates only in the x-direction, movable mass 1018 similarly moves only in the x-direction.

FIG. 11 depicts an exemplary schematic of a spring-mass system including a multi-spring flexible coupling, in accordance with an embodiment of the present disclosure. This spring-mass system is similar to and functions in a similar manner as that of the spring-mass system in FIGS. 3B, 4 and 5, with like-numbered elements corresponding to similar components. In the embodiment of FIG. 11, movable mass 1118 is nested inside of movable mass 1110 and attached to interior surfaces of movable mass 1110 via spring elements 1116a and 1116b. Flexible coupling 1108 connects between movable mass 1110 and levered component 1106, and includes a first spring element 1120 connected to levered component 1106 and second spring element 1122, which in turn connects to movable mass 1110. The first spring element 1120 extends alongside and adjacent to levered component 1106 and from levered component to a parallel connecting portion that connects to second spring element 1122, and is capable of translating both x-direction and y-direction movement between levered component 1106 and second spring element 1122 when levered component 1106 rotates. The spring 1120 may have flexibility in both x-direction and y-direction, with the spring 1120 being less flexible in the y-direction than in the x-direction. The second spring element 1122, which is compliant in the y-direction and rigid in the x-direction, extends adjacent to approximately half of the bottom surface of movable mass 1110 in the x-direction, resulting in only x-axis movement being transferred between levered component 1106 and movable mass 1110. Because movable mass 1110 oscillates only in the x-direction, movable mass 1118 similarly moves only in the x-direction.

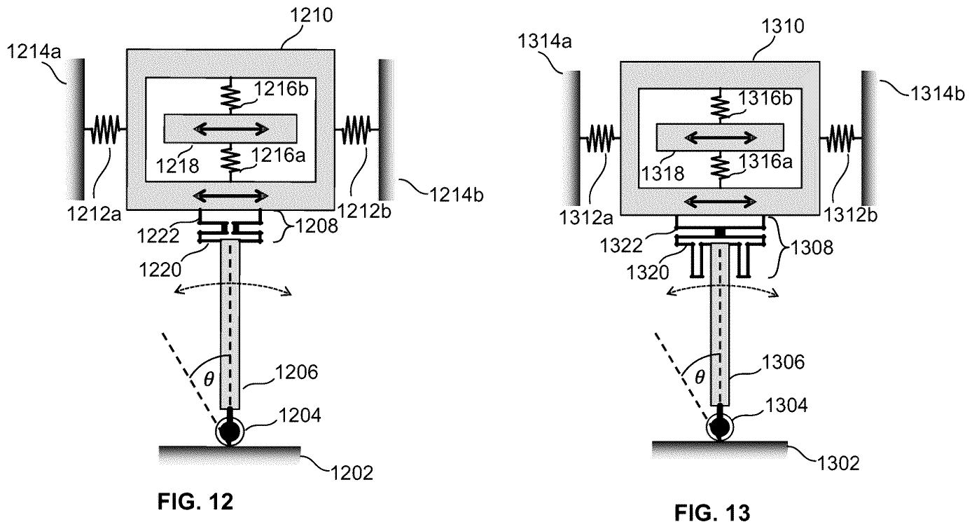

FIG. 12 depicts an exemplary schematic of a spring-mass system including a multi-spring flexible coupling, in accordance with an embodiment of the present disclosure. This spring-mass system is similar to and functions in a similar manner as that of the spring-mass system in FIGS. 3B, 4 and 5, with like-numbered elements corresponding to similar components. In the embodiment of FIG. 12, movable mass 1218 is nested inside of movable mass 1210 and attached to interior surfaces of movable mass 1210 via spring elements 1216a and 1216b. Flexible coupling 1208 connects between movable mass 1210 and levered component 1206, and includes a first spring element 1220 connected to levered component 1206 and second spring element 1222, which in turn connects to movable mass 1210. The first spring element 1220 extends from the top of and perpendicular to the length of levered component 1206 and includes a parallel connecting portion that connects to second spring element 1222, and is capable of translating primarily x-direction movement while being compliant to y-direction movement between levered component 1206 and second spring element 1222 when levered component 1206 rotates. The second spring element 1222, which is compliant in the y-direction and rigid in the x-direction, extends adjacent to the bottom surface of movable mass 1210 and parallel to first spring element 1220, resulting in only x-axis movement being transferred between levered component 1206 and movable mass 1210. Because movable mass 1210 oscillates only in the x-direction, movable mass 1218 similarly moves only in the x-direction.

FIG. 13 depicts an exemplary schematic of a spring-mass system including a multi-spring flexible coupling, in accordance with an embodiment of the present disclosure. This spring-mass system is similar to and functions in a similar manner as that of the spring-mass system in FIGS. 3B, 4 and 5, with like-numbered elements corresponding to similar components. In the embodiment of FIG. 13, movable mass 1318 is nested inside of movable mass 1310 and attached to interior surfaces of movable mass 1310 via spring elements 1316a and 1316b. Flexible coupling 1308 connects between movable mass 1310 and levered component 1306, and includes a first spring element 1320 connected to levered component 1306 and second spring element 1322, which in turn connects to movable mass 1310. The first spring element 1320 extends alongside and adjacent to an upper portion of levered component 1306, further extends perpendicular to the length of levered components 1306, and has a relatively thick terminating point that connects to second spring element 1322. First spring element 1320 is capable of translating both x-direction and y-direction movement between levered component 1306 and second spring element 1322 when levered component 1306 rotates. The second spring element 1322, which is compliant in the y-direction and rigid in the x-direction, extends adjacent to the bottom surface of movable mass 1310, resulting in only x-axis movement being transferred between levered component 1306 and movable mass 1310. Because movable mass 1310 oscillates only in the x-direction, movable mass 1318 similarly moves only in the x-direction.

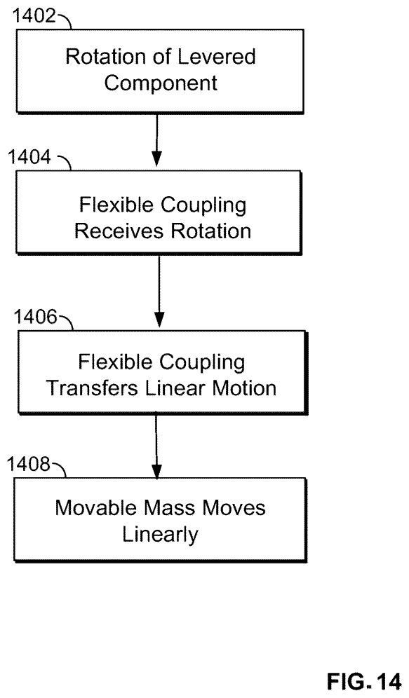

FIG. 14 depicts example steps of removing the propagation of rotational motion to movable masses in accordance with an embodiment of the present disclosure. Although particular steps are depicted in a particular order in FIG. 14, it will be understood that steps may be added, removed, or reordered in accordance with the present disclosure.

At step 1402, a levered components such as a lever arm of a MEMS inertial sensor rotates, for example, about a hinged joint to an anchored portion within a MEMS layer of the MEMS inertial sensor. As an example, a lever arm may translate oscillating drive motions between different drive axes, allowing a single drive motion to drive the system along multiple axes (e.g., in a multi-axis MEMS gyroscope). The process continues to step 1404.

At step 1404, a flexible coupling receives the rotational motion. In some embodiments, the force causing the rotational motion may be “driven” from the levered component, while in other embodiments the levered component may be “driven” via a movable mass also connected to the flexible coupling, with the levered component restricted to rotational movement via its hinged coupling such as to an anchor. The process continues to step 1406.

At step 1406, the flexible coupling transfers motion between the levered component and the movable mass. However the motion originates (e.g., via the movable mass or the levered component), the movable mass is able to maintain only a single-axis (e.g., x-axis) based on compliant and rigid directions of the flexible coupling, even while the levered components has a rotational movement. The process continues to step 1408.

At step 1408, the movable mass moves linearly. Further, any additional masses that are coupled to the movable mass for linear movement will similarly move linearly. In some configurations such as where a proof mass is connected to the movable mass, the resulting linear motion may eliminate undesired motion such as second harmonics of the rotational oscillation, resulting in a substantial reduction in noise that enables significant design improvements, such as increased resolution, reduction in filtering or noise reduction steps, and increases in sensor gain.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical system (MEMS) sensor, comprising:
a movable mass within a MEMS layer of the MEMS sensor;
a levered component within the MEMS layer that rotates within a horizontal plane of the MEMS layer about a point of rotation such that the levered component moves in both a first direction in the horizontal plane and a second direction in the horizontal plane during the rotation, wherein the first direction and the second direction are perpendicular; and
a flexible coupling that connects to the movable mass and to the levered component, wherein the flexible coupling transfers movement from the levered component to the movable mass in the first direction, and is compliant in the second direction such that the rotation of the levered component does not cause movement of the movable mass in the second direction.

2. The MEMS sensor of claim 1, wherein, in response to the rotation of the levered component, the flexible coupling has a greater overall stiffness in the first direction than in the second direction.

3. The MEMS sensor of claim 1, wherein the flexible coupling comprises a plurality of interconnected spring elements.

4. The MEMS sensor of claim 3, wherein one or more first spring elements of the plurality of interconnected spring elements are connected to an end of the levered component at a distance from the point of rotation.

5. The MEMS sensor of claim 4, wherein the one or more first spring elements move in the first direction and the second direction during the rotation of the levered component.

6. The MEMS sensor of claim 5, further comprising one or more second spring elements of the plurality of interconnected spring elements connected to the one or more first spring elements and to the movable mass, wherein the one or more second spring elements transfer movement in the first direction from the one or more first spring elements to the movable mass and are compliant in the second direction such that movement of the one or more first spring elements in the second direction is absorbed by the one or more second spring elements.

7. The MEMS sensor of claim 6, wherein the compliance of the one or more second spring elements is based on the one or more second spring elements flexing in the second direction as the levered component moves in the second direction.

8. The MEMS sensor of claim 7, wherein the transfer of the movement in the first direction by the one or more second spring elements is based on the one or more second spring elements attached to the movable mass in the first direction.

9. The MEMS sensor of claim 6, wherein the one or more first spring elements move in the first direction and the second direction during the rotation of the levered component based on a first portion of the one or more first spring elements attached to the levered component in the first direction and a second portion of the one or more first spring elements attached to the levered component in the second direction.

10. The MEMS sensor of claim 1, wherein the flexible coupling comprises a plurality of spring elements and a secondary movable mass.

11. The MEMS sensor of claim 10, wherein one or more first spring elements of the plurality of spring elements connect to the levered component and the secondary movable mass and wherein one or more second spring elements connect to the secondary movable mass and the movable mass.

12. The MEMS sensor of claim 11, wherein the one or more second spring elements transfer movement in the first direction from the secondary movable to the movable mass and are compliant in the second direction such that movement of the secondary movable in the second direction is absorbed by the one or more second spring elements.

13. The MEMS sensor of claim 12, wherein the compliance of the one or more second spring elements is based on the one or more second spring elements flexing in the second direction as the levered component and the secondary movable mass move in the second direction.

14. The MEMS sensor of claim 13, wherein the transfer of the movement in the first direction by the one or more second spring elements is based on the one or more second spring elements attached to the movable mass and the secondary movable mass in the first direction.

15. The MEMS sensor of claim 11, wherein the one or more first spring elements and the secondary movable mass move in the first direction and the second direction during the rotation of the levered component based on the secondary movable mass attached to the levered component in the first direction and the one or more first spring elements attached to the levered component in the second direction.

16. A microelectromechanical system (MEMS) sensor, comprising:
a first movable mass within a MEMS layer of the MEMS sensor;
a second movable mass within the MEMS layer and coupled to the first movable mass via one or more springs;
a levered component within the MEMS layer that rotates within a horizontal plane of the MEMS layer about a point of rotation; and
a flexible coupling that connects to the first movable mass and to the levered component, wherein the flexible coupling transfers movement from the levered component to the movable mass such that the first movable mass moves only in a first direction, and wherein the one or more springs transfer the movement in the first direction to the second movable mass without imparting a rotation on the second movable mass.

17. The MEMS sensor of claim 16, wherein the flexible coupling comprises a plurality of spring elements and a secondary movable mass.

18. The MEMS sensor of claim 16, wherein the flexible coupling comprises a plurality of interconnected spring elements.

19. A microelectromechanical system (MEMS) system, comprising:
a first movable mass within a MEMS layer of the MEMS sensor;
a second movable mass within the MEMS layer and coupled to the first movable mass via one or more springs;
a levered component within the MEMS layer that rotates within a horizontal plane of the MEMS layer about a point of rotation at a first frequency; and
a flexible coupling that connects to the first movable mass and to the levered component, wherein the flexible coupling transfers movement from the levered component to the movable mass and the one or more springs transfer movement from the first movable mass to the second movable mass such that the second movable mass does not have any rotational movement at a harmonic of the first frequency.

20. The MEMS sensor of claim 19, wherein the flexible coupling comprises a plurality of spring elements and a secondary movable mass.

21. The MEMS sensor of claim 19, wherein the flexible coupling comprises a plurality of interconnected spring elements.
